(19) United States
(12) Patent Application Publication
(10) Pub. No.: US 2015/0146316 A1
(43) Pub. Date: May 28, 2015

(54) OPTICAL FILTER AND METHOD FOR MAKING THE SAME

(71) Applicant: U.S. Army Research Laboratory ATTN: RDRL-LOC-I, Adelphi, MD (US)

(72) Inventor: Thomas C. Parker, Bel Air, MD (US)

(21) Appl. No.: 14/476,089

(22) Filed: Sep. 3, 2014

Related U.S. Application Data
(60) Provisional application No. 61/907,521, filed on Nov. 22, 2013.

(51) Int. Cl. G02B 5/22; C23C 14/30; G02B 1/12; C23C 14/08

(52) U.S. Cl. CPC G02B 5/22; C23C 14/083; C23C 14/08; C23C 14/30; G02B 1/12
USPC 359/885; 427/162; 427/586

(57) ABSTRACT

An optical filter for use in high temperature and rapid changing temperature environments, and method of making the same is provided. The optical filter includes a substrate and a filter layer disposed on the substrate. The filter layer has a porous columnar micro-structure configured to decouple the thermal expansion stress between the substrate and the filter layer when the optical filter is subjected to high temperature. The filter layer may be formed of a material conducive to physical vapor deposition, such as metallic oxide. The filter layer is deposited onto the substrate at an angle.

### CROSS-REFERENCE TO RELATED APPLICATIONS

This patent application claims the benefit of U.S. provisional application 61/907,521 filed on Nov. 22, 2013 (attorney docket no. ARL 13-08P) and titled “High Temperature Optical Filters that can withstand Oxidizing Environments” listing Dr. Thomas Christopher Parker as sole inventor which is hereby incorporated by reference herein including all attachments thereto, including a presentation to the Materials Research Society dated Nov. 28, 2012 titled “Development of High temperature Optical filters”.

### GOVERNMENT INTEREST

The invention described herein may be manufactured, used, and licensed by or for the United States Government.

### FIELD OF THE INVENTION

The present invention relates to an optical filter configured to withstand a high rate of temperature change and a method of making the same.

### BACKGROUND OF THE INVENTION

Optical filters are currently known and used in thermal photovoltaic applications. Such applications may subject the optical filter to temperatures up to 1000° C. The optical filters have a thin film layer, typically formed of a metallic oxide, disposed on top of a substrate. However, due to the coefficient of thermal expansion differences between the thin film layer and the substrate, the thin film layer may decoupled from the substrate or become physically damaged under such temperatures.

Oblique angle deposition is a self-organizing physical vapor deposition technique that has been used to grow sculpted 3D nanostructures including helices, slanted rods, and zigzag structures. However, oblique angle deposition has been limited to applications in the spectral range measured in nanometers wherein high temperature compatibility and vacuum stability conditions are not addressed. Accordingly, it remains desirable to have an optical filter configured to maintain its intended functional performance under high temperatures, and dramatic temperature changes.

### SUMMARY OF THE INVENTION

An optical filter is provided. The optical filter includes a substrate and a filter layer disposed on the substrate. The filter layer has a porous columnar micro-structure configured to decouple the thermal expansion stress between the substrate and the filter layer when the optical filter is subjected to high temperature. The filter layer may be formed of a metallic oxide, and the porosity of the columnar micro-structure may be between bulk density and 90%.

A method for making an optical filter having a porous columnar micro-structure configured to decouple the thermal expansion stress between the substrate and the filter layer when the optical filter is subjected to high temperature is also provided. The method includes the step of providing a substrate. The method proceeds to the step of depositing a material onto the substrate utilizing physical vapor deposition and wherein said materials are deposited at an angle with respect to the substrate, between 0 degrees or normal to the substrate surface and 90 degrees or almost completely parallel to the substrate surface. The method may also include the step of depositing a second material on top of the first material, wherein the first and second material are metallic oxides, and the first and second material are different from each other.

### BRIEF DESCRIPTION OF THE DRAWINGS

FIG. 1A is an illustrative cross-sectional view of the optical filter;

FIG. 1B is an illustrative cross-sectional view of the optical filter having two layers;

FIG. 2 is an illustrative view of a porous columnar micro-structure of FIG. 1B;

FIG. 3 is a diagram showing the steps for a method of making an optical filter;

FIG. 4 is a chart showing the RBS spectrum of an as-deposited filter on an Si substrate;

FIG. 5A is a chart showing the reflectance spectroscopy of Si substrate samples;

FIG. 5B is a chart showing the reflectance spectroscopy of sapphire substrate samples; and

FIG. 6 is a chart showing the reflectance spectroscopy of Si substrate having a native oxide.

### DETAILED DESCRIPTION OF THE INVENTION

An optical filter 10 configured to operate under high temperature and dramatic temperature changes, and a method of making the same is provided. The optical filter 10 includes a substrate 12 and a filter layer 14 disposed on the substrate 12. The filter layer 14 has a porous columnar micro-structure 16 configured to decouple the thermal expansion stress between the substrate 12 and the filter layer 14 when the optical filter 10 is subjected to high temperature.

The filter layer 14 may be formed of a metallic oxide, and the porosity of the columnar micro-structure 16 may be between near bulk density, and about 90%. For use herein bulk density shall mean the density of the metallic oxide in its natural state or as supplied by a manufacturer of said metallic oxide. The filter layer 14 may have a thickness of at least about 100 nanometers, but may be increased based upon the dimensions and operating conditions of the device for which the filter is designed to be used in, such as a thermal photovoltaic power system.

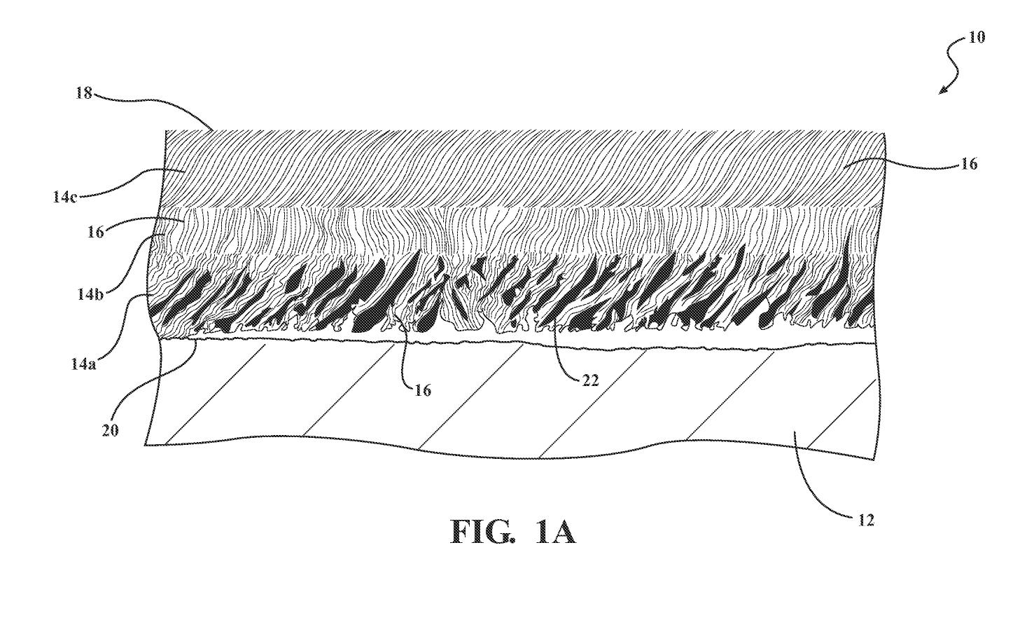

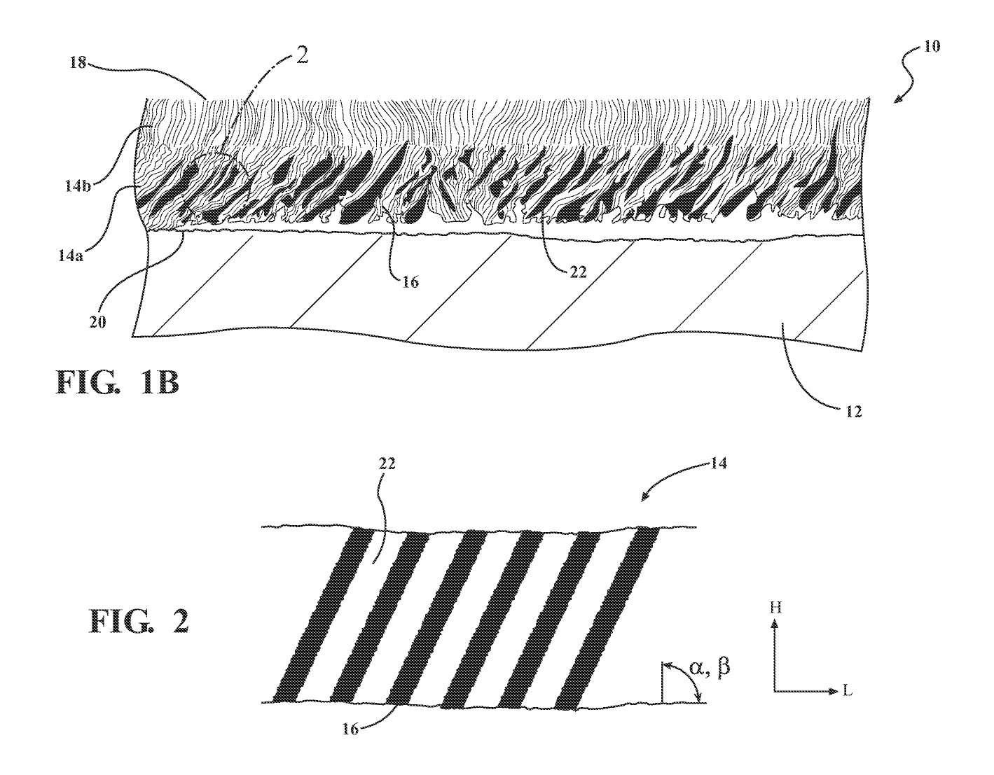

With reference now to FIGS. 1A and 1B, a cross-section view of embodiments of the optical filter 10 is provided. The substrate 12 may be formed from a material configured to allow light to pass. Such material illustratively include, but is not limited to, silicon dioxide, sapphire, and so forth. The substrate 12 may be planar, or may include contours, or be generally concave or convex to as to provide for a desired reflective property. The substrate 12 may be configured to be used in conjunction with a thermal photovoltaic power system.

At least one thin film layer 14, also referenced as a “filter layer,” is disposed on the substrate 12. FIG. 1A shows one embodiment wherein the optical filter 10 includes three filter layers 14a, 14b, 14c, and FIG. 1B shows an embodiment wherein the optical filter 10 includes two filter layers 14a, 14b.

The thin film layer 14 is formed of a material configured to reject wavelength light from entering the substrate 12. For instance, the thin film layer 14 may be formed of a metallic oxide, to include SiO₂, Y₂O₃, and so forth. It should be appreciated that the metallic oxide is of a material suitable for physical vapor deposition. For use herein, physical vapor deposition is a process to form a thin film, typically in a vacuum, by the condensation of a vaporized form of the desired thin film material. Preferably, the filter layer 14 has a material thickness of at least 100 nanometers, as measured by the distance between the top and bottom surfaces 18, 20 of the filter layer 14.

With reference now to FIG. 2, an illustrative view of a filter layer 14 is provided. The filter layer 14 is formed by the materials arranged in a columnar micro-structure 16. The porosity of the columnar micro-structure 16 shown in FIG. 2 is approximately 95%. However, it should be appreciated that the porosity of the columnar micro-structure 16 may be between near bulk density and 90% so as to provide the filter layer 14 with the ability to decompress in response to the thermal expansion of the substrate 12.

With reference again to FIG. 2, the filter layer 14 has a columnar micro-structure 16. The filter layer 14 includes pockets of space 22 having a tubular dimension extending axially along the height of the filter layer 14 as indicated by the letter “H” shown in FIG. 2. Thus, the filter layers have a plurality of pockets of space 22 shaped in a column, each separated from each other by the columnar micro-structure 16 of the metallic oxide.

As used herein the term micro-structure references a size having a volumetric size ranging from 4 nm³ to 5×10⁹ nm³, and the term columnar refers to the tubular dimension of the deposited material. Thus, the term columnar microstructure describes a material having a tubular dimension and of a size having a volumetric size ranging from about 4 nm³ to about 5×10⁹ nm³. The columnar micro-structure 16 is slanted/angled with respect to the substrate 12 along its height. It should be appreciated that the illustration shown in FIG. 2 is provided for illustrative purposes only and that the pockets of space 22 may also be angled.

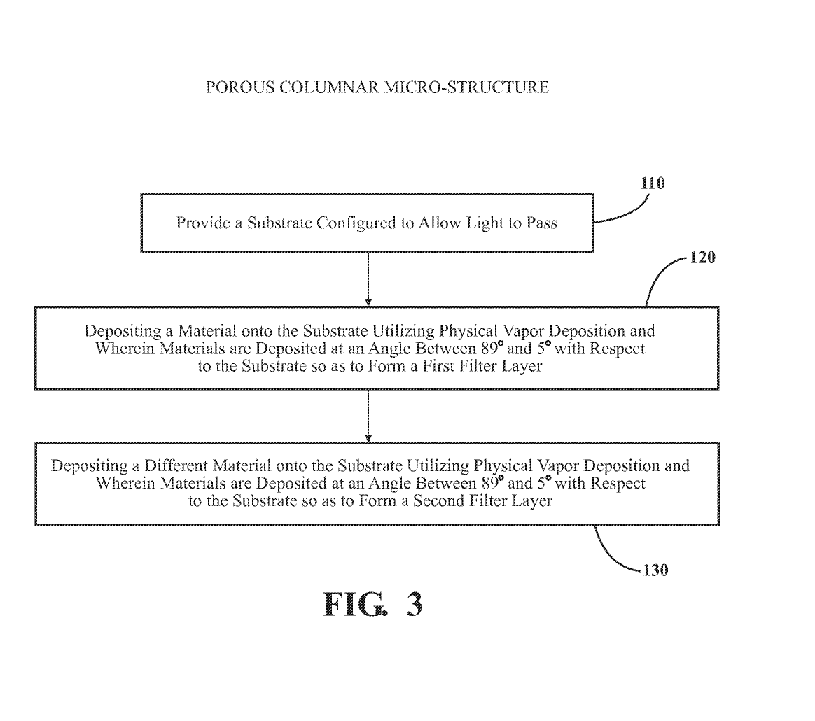

With reference now to FIG. 3, a method 100 of making an optical filter 10 having a porous columnar micro-structure 16 configured to decouple the thermal expansion stress between the substrate 12 and the filter layer 14 when the optical filter 10 is subjected to high temperature is also provided. The method includes step 110, providing a substrate 12. The substrate 12 may be formed from a material configured to allow light to pass. Such material illustratively include, but is not limited to, silicon dioxide, sapphire, and so forth. The substrate 12 may be planar, or may include contours, or be generally concave or convex to as to provide for a desired reflective property. The substrate 12 may be configured to be used in conjunction with thermal photovoltaic power system.

The method proceeds to the step 120, depositing a material, also referenced below as a “first material,” onto the substrate 12 utilizing physical vapor deposition so as to form a first filter layer 14a. The filter layer 14 is configured to filter light in a predetermined wavelength. The material is deposited at an angle a which may be between about 89° and about 5° with respect to the substrate 12. For use herein, the angle is measured from the planar surface of the substrate 12 as shown in FIG. 2.

The first material is of the type that is capable of being deposited using physical vapor deposition, and has a reflective property capable of rejecting long wavelength light. Any such material currently known and used in the art may be adapted for use herein, illustratively include metallic oxides. The vapor deposition is conducted so as to form a layer of the material having a porous columnar micro-structure 16. It should be appreciated that the material itself forms a porous columnar micro-structure 16, and thus the filter layer 14 will include pockets of space 22 adjacent the porous columnar micro-structure 16 which are tubular in dimension, having a length as defined between the top and bottom surfaces of the layer. The term columnar microstructure refers to the tubular dimensions described herein being of a size having a volumetric size ranging volumetric size ranging from 4 nm³ to 5×10⁹ nm³.

The method may further include step 130, wherein a second material is deposited onto the first material, so as to form a second filter layer 14b. The second material is different than the first material. The second material may have a material thickness smaller than that of the first material. The second filter layer 14 is configured filter light in a different wavelength than the first filter layer. Preferably the second material is deposited at an angle β, which may be between 89° and 5° with respect to the substrate 12. Angle β is different than angle α. For use herein, angle β is measured from the planar surface of the substrate 12 as shown in FIG. 2.

The deposition may be conducted using an electron beam, wherein the material is cryogenically pumped into the electron beam. The electron beam may be positioned at a distance between 30 cm and 50 cm from the substrate 12, and is angled with respect to the substrate 12 at an angle between 89° and 5° with respect to the substrate 12.

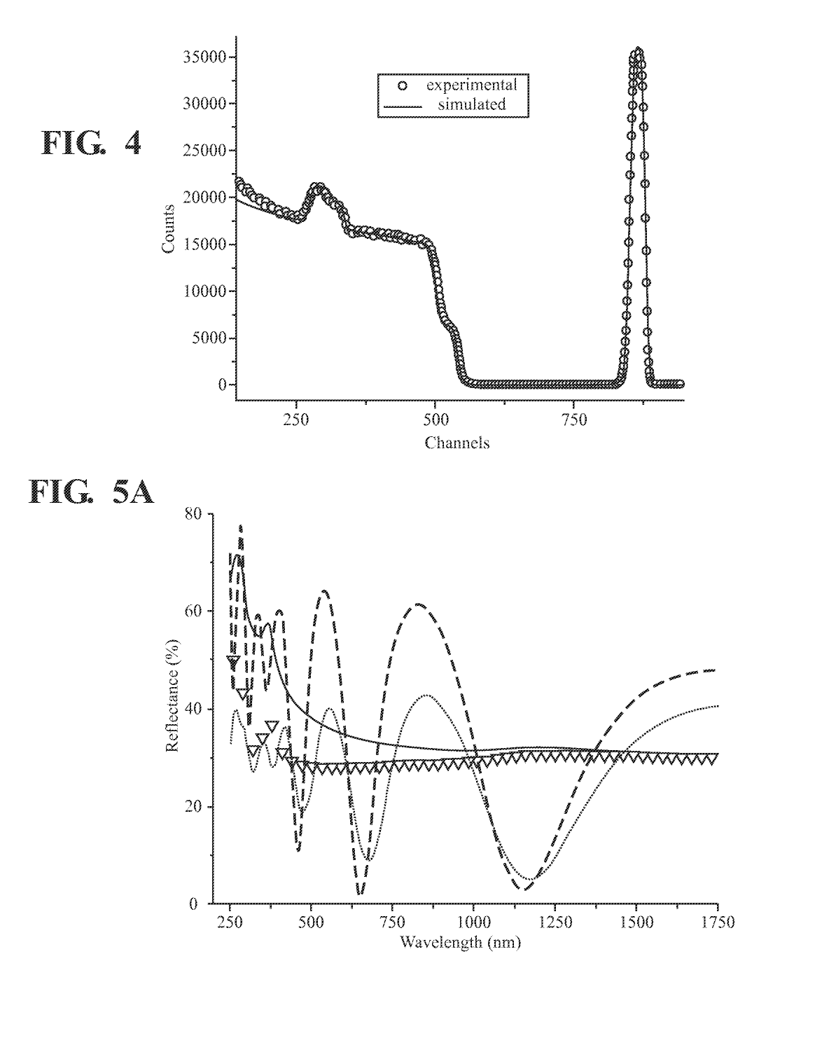

In order to better teach the invention but not to limit its scope in any way, one or more example is provided in conjunction with FIGS. 4-6. The following examples were produced using a cryogenically pumped four pocket electron beam deposition system. Two of the pocket electron beams were loaded with SiO₂ (K. J. Lesker, purity 99.99%) and Y₂O₃ (K. J. Lesker, purity 99.99%) pieces, respectively. The deposition rate and total thickness attained was monitored using a Sycon STM-100 monitor and a Sycon VSO-100 quartz crystal microbalance (QCM) positioned next to the sample. The base pressure of the system was 1×10-7 Torr and the pressure during deposition was approximately 7×10-7 Torr; no effort was made to control the partial pressure of oxygen during deposition by backfilling the chamber during deposition. The distance between the ebeam source and the substrate 12 was fixed at 40 cm, and the angle between the sample normal with respect to the incoming atomic flux was 82° for the porous SiO₂ layer and 0°·for the subsequent Y₂O₃ capping layer. Polished silicon and sapphire substrate 12s were placed in the chamber adjacent to each other for simultaneous deposition. After deposition each sample was cleaved into smaller pieces, one of which was annealed at 1000° C. in a quartz tube furnace for 90 minutes in a dry air flow of 300 Sccm.

FIG. 4 shows the RBS spectrum of a deposited filter layer 14 on a silicon substrate 12 is shown (black circles), with a best fit simulated spectrum obtained using SIMNRA (solid line). The RBS analysis showed that both the SiO₂ and Y₂O₃ layers were stoichiometric. The thickness of the SiO₂ layer was found to be ˜530 nm and the thickness of the Y₂O₃ was ˜95 nm. There were no significant differences in the spectra between films grown on sapphire or silicon substrate 12 after deposition. After annealing, however, there was evidence of significant oxidation underneath the deposited film on a silicon substrate 12. A bare silicon substrate 12 placed in the tube furnace also oxidized to a similar extent, and both RBS and VASE examination of these samples confirmed an oxide thickness of approximately 42 nm underneath the deposited layer after annealing.

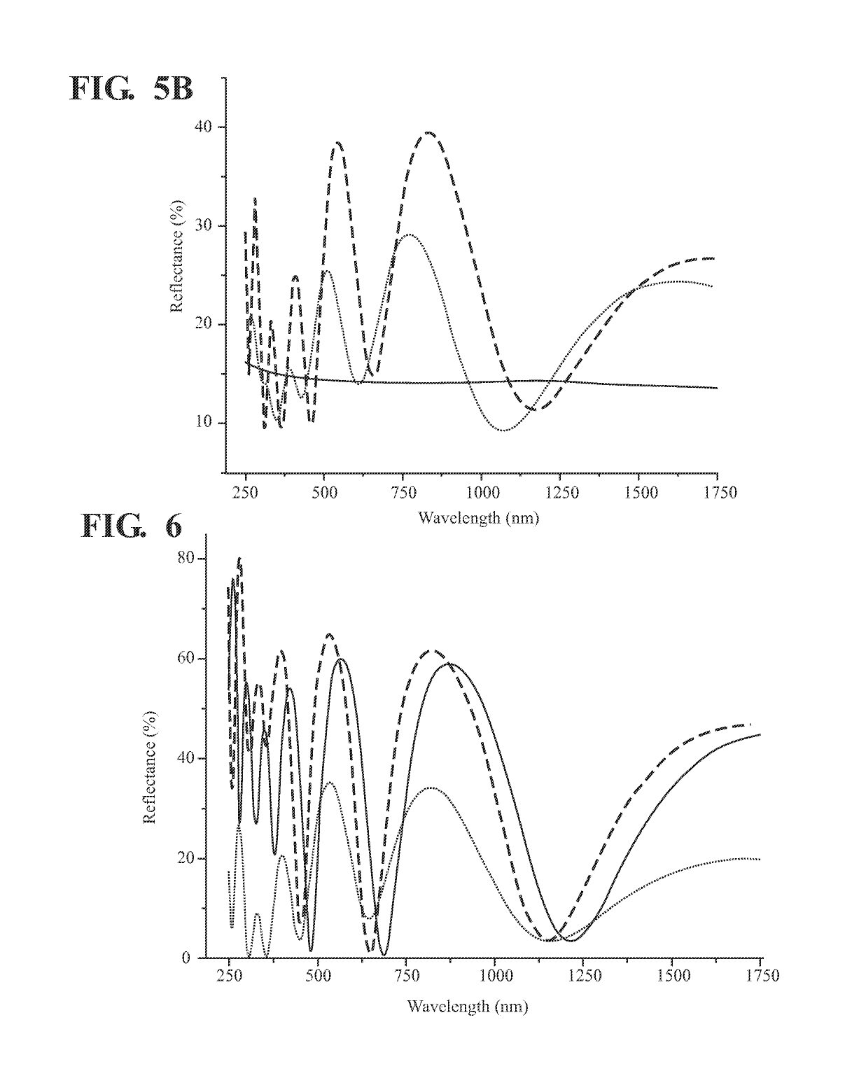

FIGS. 5A and 5B show the reflectance spectra of the films before (long dash line) and after annealing (short dash line) for films deposited on silicon, FIG. 2a, and films deposited on sapphire, FIG. 2b, with the as deposited (long dash line) and post anneal (short dash line), along with reference spectra from bare substrate 12s. The bare sapphire substrate 12 is shown in FIG. 2b (solid line).

In FIG. 5A the Si (solid line) substrate 12 and oxidized Si with no significant features at wavelengths longer than 500 nm. The optical features evident in FIGS. 5A and 5B at longer wavelengths, therefore, are entirely due to the deposited SiO₂/Y₂O₃ filter. There are slight changes in the optical properties of the filters after annealing, primarily a reduction in overall reflectance on all samples, likely due to increased surface roughness and diffuse scattering. Most spectral features remain unchanged in wavelength, with very small shifts either toward longer wavelengths (samples on silicon) or shorter wavelengths (samples on sapphire).

The red wavelength shift in FIG. 5A is likely due to the growth of the 42 nm thermal oxide under the filter, as discussed in the RBS section above. However, there could be compaction of the SiO₂ which would reduce the red shift, as will be discussed below. The blue wavelength shift noted in the annealed filters on sapphire (FIG. 2b) could be due to compaction of the porous SiO₂ during annealing.

The reflectance of the thin films stacks were simulated using the Essential Macleod software. In FIG. 6 the black curve (long dash) shows the reflectance with respect to wavelength for a Si wafer with a native oxide of 2.7 nm followed by a 550 nm thick/65% porous SiO₂ layer with a 100 nm thick Y₂O₃ capping layer. The optical index of 1.15 for the porous SiO₂. The model for the blue curve (solid line) uses the same film stack with the addition of a 42 nm thick thermal oxide to represent the annealed sample A, i.e. Si substrate 12 sample.

The red curve (short dash) shows the same film stack as the black curve but without the native oxide (SiO₂) on an Al₂O₃ (sapphire) substrate 12. Similar to that shown in FIG. 2a for filters on silicon (pre and post anneal), the simulated blue and black curves show a red shift but much more pronounced than was observed experimentally. It may be concluded, similar to filters on sapphire, that filters on silicon must also be undergoing compaction of the porous SiO₂, the blue shift from compaction is being masked by the larger red shift due to substrate 12 oxide growth.

Experiments show that the optical filter 10s described herein have been shown to withstand high temperatures (1000° C.) in air for 90 minutes without delamination or significant degradation of their optical properties, even when the substrate 12 underneath the filter is undergoing significant oxidation. The basic spectral characteristics of the reflectance data were preserved after the samples were annealed, it should be understood by those skill in the art that the small shifts seen in the reflectance spectra may be attributed to compaction of the porous filter layer.

It should be appreciated that the optical filter 10 described herein may be suitable for use in: 1) high temperature optical filter 10s in TPV systems; 2) high temperature optical sensors in harsh environments including, but not limited to, a) turbines, jet engines, gas fired power generating turbines, rocket motors, and so forth and b) drilling: oil/gas/mineral exploratory (or active well) monitoring; 3) high temperature oxidation resistant heat shields including, but not limited to a) applications in nuclear power generation systems and b) in turbines/engine/motor heat shielding. The optical filter 10 may be designed to withstand 1000° C., as well as a high rate of temperature change, for example 25° C. to 1000° C. in several seconds. Further, the optical filter 10s that can survive in an oxidizing environment at elevated temperatures, for example temperatures greater than 500° C., greater than 600° C., greater than 700° C., as high as 800° C., as high as 900° C. and even as high as 1000° C. Further, the porous columnar micro-structure 16 decouples the thermal expansion stress between the substrate 12 and filter layers.

It is appreciated that changes, modifications, and so forth can be made by those skilled in the art and still fall within the scope of the present invention. As such, the scope of the invention is provided by the claims and all equivalents thereof.

I claim:

1. An optical filter comprising:
a substrate;
at least one filter layer disposed on the substrate, the at least one filter layer having a porous columnar micro-structure configured to decouple the thermal expansion stress between the substrate and the at least one filter layer.

2. The optical filter as set forth in claim 1, wherein the porous columnar microstructure is angled with respect to the substrate.

3. The optical filter as set forth in claim 1, wherein the at least one filter layer is formed from a metallic oxide.

4. The optical filter as set forth in claim 1, wherein the porous columnar micro-structure has a volumetric size between 4 nm³ and 5×10⁹ nm³.

5. The optical filter as set forth in claim 1, wherein the substrate is formed of aluminum oxide.

6. The optical filter as set forth in claim 1, wherein the substrate is formed of silicon.

7. The optical filter as set forth in claim 1, wherein the at least one filter layer includes a first layer, and a second layer each having a porous columnar micro-structure, the first layer formed of a first metallic oxide, the second layer formed a second metallic oxide, the second metallic oxide is different than the first metallic oxide.

8. The optical filter as set forth in claim 7, wherein the first metallic oxide is SiO₂ and the second metallic oxide is Y₂O₃.

9. The optical filter as set forth in claim 7, wherein the porous columnar micro-structure of the first layer is slanted at an angle differently that the porous columnar micro-structure of the second layer.

10. A method of making an optical filter having a porous columnar micro-structure configured to decouple the thermal expansion stress between the substrate and the filter layer when the optical filter is subjected to high temperature, the method comprising the steps of:
providing a substrate;
depositing a first material onto the substrate utilizing physical vapor deposition and wherein the first material is deposited at an angle between 89 and 5 with respect to the substrate.

11. The method as set forth in claim 10, wherein the first material is a metallic oxide.

12. The method as set forth in claim 11, wherein a second material is deposited, the second material is different than the first material.

13. The method as set forth in claim 12, wherein the second material is deposited onto the first material at an angle different than that of the first material, wherein the second material is deposited at an angle between 89 and 5 with respect to the substrate.

14. The method as set forth in claim 10, wherein the deposited material is deposited using an electron beam.

15. The method as set forth in claim 14, wherein the deposited material is cryogenically pumped.

16. The method as set forth in claim 10, wherein the distance between the electron beam and the substrate is between 30 and 50 centimeters.
